(19) United States
(12) Patent Application Publication
(10) Pub. No.: US 2006/0091355 A1
(43) Pub. Date: May 4, 2006

(54) Solution and method for removing ashing residue in Cu/low-k multilevel interconnection structure

(75) Inventors: Mitsushi Itano, Settsu-shi (JP); Takehiko Kezuka, Settsu-shi (JP); Takashi Kanemura, Settsu-shi (JP)

Correspondence Address: SUGHRUE MION, PLLC, 2100 PENNSYLVANIA AVENUE, N.W., SUITE 800, WASHINGTON, DC, 20037, US

(73) Assignee: DAIKIN INDUSTRIES, LTD.

(21) Appl. No.: 11/259,128

(22) Filed: Oct. 27, 2005

(30) Foreign Application Priority Data
Oct. 28, 2004 (JP) 2004-314561
May 2, 2005 (JP) 2005-134250

(51) Int. Cl. C09K 13/00; B44C 1/22; H01L 29/00; H01L 21/302

(52) U.S. Cl. 252/79.1; 216/95; 438/745; 257/499

(57) ABSTRACT

The present invention relates to a removing solution for removing ashing residue formed by dry etching and/or ashing on a Cu/low-k multilevel interconnection structure, wherein the removing solution comprises 0.007 to 0.04 mol/kg of acid, a nonmetallic fluoride salt whose concentration is at least 20 times as great as that of the acid, and water.

### TECHNICAL FIELD

The present invention relates to a removing solution for inhibiting the etching of low-k film or silicon-containing film by chemical solutions and selectively removing the ashing residues formed in Cu/low-k multilevel interconnection structures during ashing, irrespective of the presence or absence of unwanted substances such as resists, antireflection coatings, filling materials, and dry etching residues, in the formation of damascene and dual damascene structures for the Cu/low-k multilevel interconnection structures, in the reworking of processes such as lithography, and in other semiconductor production processes or in liquid crystal panel elements. The present invention also relates to a method for removing such ashing residues using this removing solution.

### BACKGROUND ART

Until recently, mainstream semiconductor devices have had an Al/SiO₂ multilevel interconnection structure, which uses aluminum, aluminum alloy or the like as a wiring material, and a SiO₂ film as an interlayer dielectric. In order to reduce the wiring delay caused by the microminiaturization of devices, semiconductor devices with a Cu/low-k multilevel interconnection structure are now being developed, using Cu, which has low resistance, as a wiring material, and a low-k film (low dielectric constant film), which has low interconnect capacitance, as an interlayer dielectric in place of the SiO₂ film.

Cu/low-k multilevel interconnection structures are produced by a process called damascene, wherein the wiring structure is obtained by forming trenches or holes (via holes) in low-k film by dry etching, and then filling the trenches or holes with a wiring material such as copper. In the method called dual damascene, trenches for wiring and via holes are formed simultaneously in low-k film, and then filled with a wiring material such as copper.

A dual damascene structure can be formed by a via-first process, wherein the via holes are formed prior to the trenches for wiring; or conversely, by a trench-first process, wherein the trenches for wiring are formed prior to the via holes; or by other processes such as a middle-first process, a dual hard mask process, or a triple hard mask process.

In many cases of the via-first process, filling materials are used. In such a process, via holes are formed by dry etching and then filled with a filling material, followed by lithography and dry etching for the formation of trenches. Thereafter the filling material is selectively removed. In contrast, no filling material is used in processes such as the dual hard mask process, the triple hard mask process, etc.

In the Al/SiO₂ multilevel interconnection structure, after the metal etching for wiring or the via etching for via hole formation, ashing is performed using an oxygen radical-containing plasma to remove unwanted substances such as resist, antireflection coating, and etching residues.

In the Cu/low-k multilevel interconnection structure, in contrast, if ashing is performed using a plasma containing a large number of oxygen radicals, the low-k film will be damaged. Therefore, it is preferable not to perform ashing with a plasma containing a large number of oxygen radicals, but to carry out hydrogen plasma ashing, ashing with inert gases such as He, ashing with a plasma of a mixture of gases such as He/hydrogen, or ashing using an oxygen-containing plasma with a decreased number of oxygen radicals so as not to damage the low-k film, and thereafter removing unwanted substances such as resist and dry etching residues. Even when such ashing methods are used, inorganic residues such as resist, antireflection coating, dry etching residue, and filling material may remain. In a damascene or dual damascene structure, when trenches and via holes are filled with metals such as TaN as a barrier metal and Cu as a wiring material, ashing residues remaining in the via holes and on the trench surface lead to defective semiconductor devices. Therefore, such ashing residues must be selectively removed, including when the lithography of semiconductor circuit patterns is reworked.

If commercially available conventional removing solutions for polymers such as resist are used to remove the ashing residue produced by dry etching and/or ashing in the Cu/low-k multilevel interconnection structure, they etch copper and device-constituting films such as low-k film and cannot achieve sufficiently selective removal. As a result, accurate processing as originally designed cannot be performed. In particular, damaged low-k films tend to undergo sidewall etching (critical dimension loss) in the form of, for example, slits and peeling.

For example, for a damaged Cu/low-k multilevel interconnection structure, if hydrochloric acid or hydrofluoric acid diluted with water is used to remove ashing residues, although inorganic ashing residues can be removed, the copper tends to be corroded due to a large amount of dissociated H⁺.

When unwanted substances such as resist, antireflection coating, filling material, and dry etching residues coexist around the Cu/low-k multilevel interconnection structure, they cannot be removed by the use of hydrochloric acid or hydrofluoric acid diluted with water, and, therefore, uniform removal cannot be achieved. Furthermore, an interlayer dielectric damaged by dry etching is heavily etched by chemical solutions especially when the interlayer dielectric is porous low-k, with the result that accurate processing as originally designed cannot be performed.

As described above, for all processes for forming damascene and dual damascene structures, no chemical solutions existed or have been developed that can be used for exclusively removing ashing residues in Cu/low-k multilevel interconnection structures.

WO 99/21220 discloses a cleaning agent for copper film after CMP; however, it does not refer to the removal of the ashing residue left after ashing.

Japanese Unexamined Patent Publication No. 1998-256210 discloses a cleaning liquid for removing the residue after ashing in a process using conventional Al wiring; however, it makes no mention of the removal of ashing residues in Cu/low-k multilevel interconnection structures.

### DISCLOSURE OF THE INVENTION

An object of the present invention is to provide a removing solution for inhibiting chemical solution etching of silicon-containing film or low-k film, inhibiting copper corrosion, and selectively removing ashing residue formed on a Cu/low-k multilevel interconnection structure in the formation of a damascene or dual damascene structure for the Cu/low-k multilevel interconnection structure.

The present inventors found that ashing residues in Cu/low-k multilevel interconnection structures can be selectively removed in a short time by the use of a solution comprising specific concentrations of acid and nonmetallic fluoride salt. Based on this finding, the inventors have accomplished the present invention.

Specifically, the present invention provides the following removing solutions, removing methods, and removal-treated objects.

1. A removing solution for removing residue formed by dry etching and/or ashing on a Cu/low-k multilevel interconnection structure, wherein the removing solution comprises 0.007 to 0.04 mol/kg of acid, an organic or inorganic nonmetallic fluoride salt whose concentration is at least 20 times as great as the concentration of the acid, and water.

2. A removing solution according to item 1, wherein the acid is HF or a carboxylic acid optionally substituted with fluorine.

3. A removing solution according to item 1, wherein the acid is HF, acetic acid, or H(CF₂CF₂) COOH (wherein n is an integer from 2 to 4).

4. A removing solution according to item 1, wherein the organic or inorganic nonmetallic fluoride salt is ammonium fluoride.

5. A removing solution according to item 1, further comprising a surfactant.

6. A removing solution according to item 1, further comprising an anticorrosive.

7. A method for removing ashing residue, comprising bringing a removing solution according to any one of items 1 to 6 into contact with an object to be removal-treated, wherein the object to be removal-treated has, on a surface thereof, ashing residue formed by dry etching and/or ashing on the Cu/low-k multilevel interconnection structure.

8. A removal-treated object obtained by a method according to item 7.

The removing solution of the present invention is capable of inhibiting etching of a low-k film by the removing solution, inhibiting the corrosion of copper wiring, and selectively removing ashing residues on the low-k film, on the sides and bottom of via holes and trenches, etc.

The removing solution of the present invention for ashing residues on a Cu/low-k multilevel interconnection structure (hereinafter referred to as the “removing solution of the present invention”) is characterized in that it selectively dissolves or strips ashing residues, thus removing them while causing hardly any or no slitting or peeling (sidewall etching) in the Cu/low-k film, and that it has the effect of preventing copper corrosion.

The removing solution of the present invention is suitable for removing ashing residues in wafers with copper (Cu) deposited as an electrically conductive metal.

Such ashing residues in damascene processes such as single damascene and dual damascene may be, for example, resist or polymer residues formed by dry etching or residues mainly composed of inorganic substance remaining after the removal of filling material by ashing.

The removing solution of the present invention comprises acid, nonmetallic fluoride salt, and water in specific proportions. The removing solution is capable of enhancing the solubility of ashing residues formed by dry etching and/or ashing on a Cu/low-k multilevel interconnection structure while maintaining the effect of preventing copper corrosion.

Examples of acids used in the present invention include inorganic acids and organic acids.

Examples of such inorganic acids include HF, HCl, H₃PO₄, H₂SO₄, etc.

Examples of such organic acids include carboxylic acids such as optionally fluorinated monocarboxylic acids and polycarboxylic acids; and sulfonic acids.

Such optionally fluorinated monocarboxylic acids may be at least one member selected from the group consisting of formic acid, acetic acid, propionic acid, butyric acid, isobutyric acid, valeric acid, caproic acid, caprylic acid, enanthic acid, octanoic acid, trimethylacetic acid, monochloroacetic acid, dichloroacetic acid, trichloroacetic acid, monofluoroacetic acid, difluoroacetic acid, trifluoroacetic acid, monobromoacetic acid, dibromoacetic acid, tribromoacetic acid, α-chlorobutyric acid, β-chlorobutyric acid, γ-chlorobutyric acid, lactic acid, acrylic acid, glycolic acid, glyceric acid, pyruvic acid, glyoxalic acid, acetoacetic acid, benzylic acid, anthranilic acid, carbamic acid, oxamic acid, perfluoropropionic acid, perfluorobutanoic acid, perfluoropentanoic acid, perfluorohexanoic acid, perfluoroheptanoic acid, perfluorooctanoic acid, perfluorononanoic acid, perfluorodecanoic acid, perfluoroundecanoic acid, perfluorododecanoic acid, 3,3,3-trifluoro-2-(trifluoromethyl)propionic acid, 3H-tetrafluoropropionic acid, 5H-octafluoropentanoic acid, and 7H-dodecafluoroheptanoic acid.

Examples of sulfonic acids include optionally fluorine-substituted alkyl sulfonic acids such as methanesulfonic acid, ethanesulfonic acid, propanesulfonic acid, butanesulfonic acid, pentanesulfonic acid, hexanesulfonic acid, heptanesulfonic acid, octanesulfonic acid, trifluoromethanesulfonic acid, taurine, and cysteic acid; optionally substituted aryl sulfonic acids such as benzenesulfonic acid and toluenesulfonic acid; etc.

Such polycarboxylic acids may be at least one member selected from the group consisting of oxalic acid, malonic acid, succinic acid, glutaric acid, adipic acid, suberic acid, azelaic acid, maleic acid, fumaric acid, tartaric acid, malic acid, and citric acid.

Preferable examples of organic acids include formic acid, acetic acid, butyric acid, monochloroacetic acid, dichloroacetic acid, trichloroacetic acid, monofluoroacetic acid, difluoroacetic acid, trifluoroacetic acid, monobromoacetic acid, dibromoacetic acid, tribromoacetic acid, perfluoropropionic acid, perfluorobutanoic acid, perfluoropentanoic acid, perfluorohexanoic acid, perfluoroheptanoic acid, perfluorooctanoic acid, perfluorononanoic acid, perfluorodecanoic acid, perfluoroundecanoic acid, perfluorododecanoic acid, 3,3,3-trifluoro-2-(trifluoromethyl)propionic acid, 3H-tetrafluoropropionic acid, 5H-octafluoropentanoic acid, 7H-dodecafluoroheptanoic acid, methanesulfonic acid, etc.

Since the organic acids in the present invention dissolve in water within the concentration range of 0.007 to 0.04 mol/kg, their composition is not readily changed by the evaporation or consumption of components; and even if the composition is somewhat changed, a sufficient quantity of acid can be supplied to the ashing residue. Therefore, ashing residue can be removed in a very reliable manner.

In the removing solution of the present invention, the concentration of nonmetallic fluoride salt is preferably at least 20 times, for example 20 to 500 times, and in particular about 30 to about 300 times, as great as the concentration of organic acid in molar ratio.

The concentration of nonmetallic fluoride salt is within the range of about 0.15 to about 20 mol/kg, and preferably within the range of about 0.225 to about 12 mol/kg (with the proviso that the molar concentration of nonmetallic fluoride salt is at least 20 times as great as that of acid).

Examples of nonmetallic fluoride salts include ammonium fluoride (NH₄F), hydroxylamine fluoride salts, alkanolamine fluoride salts, fluoride salts of primary, secondary, and tertiary amines represented by NR₃, alicyclic amines, heterocyclic amines, etc.

Examples of hydroxylamines include hydroxylamine and N,N-diethylhydroxylamine.

Examples of alkanolamines include monoethanolamine, diethanolamine, and triethanolamine.

In NR₃, the three Rs may be the same or different, and each individually represents a hydrogen atom or a hydrocarbon group optionally substituted with fluorine(s), with the proviso that the three Rs are not all hydrogen atoms.

Such a hydrocarbon group optionally substituted with fluorine(s) is preferably a linear or branched C₁ to C₈ alkyl group optionally substituted with fluorine(s).

Examples of compounds represented by NR₃ are aliphatic amines, including primary amines such as methylamine and ethylamine, secondary amines such as dimethylamine and diethylamine, and tertiary amines such as trimethylamine and triethylamine.

Examples of alicyclic amines include cyclohexylamine, dicyclohexylamine, etc.; and examples of heterocyclic amines include pyrrolidine, morpholine, piperidine, N-hydroxyethylpiperidine, etc.

Examples of quaternary ammonium fluoride salts include tetramethylammonium fluoride (TMAF), tetraethylammonium fluoride, etc.

Preferable examples of fluoride salts in the present invention include ammonium fluoride, ethylamine fluoride salt, diethylamine fluoride salt, triethylamine fluoride salt, methylamine fluoride salt, dimethylamine fluoride salt, trimethylamine fluoride salt, ethanolamine fluoride salt, etc.

The amounts of components in the present invention are preferably as follows:

Acid:Fluoride salt:Water=0.007-0.04 mol/kg:0.15-20 mol/kg:balance

The amounts of components in the present invention are more preferably as follows:

Acid:Fluoride salt:Water=0.007-0.04 mol/kg:0.225-12 mol/kg:balance

Typically, the removing solution of the present invention removes Si-containing residues, copper oxides and/or modified copper layers (formed on a copper surface by dry etching, ashing, etc.), inorganic filling material-originated residues, etc., and such objects to be removed are mainly composed of inorganic substances. However, the removing solution of the invention is also capable of removing at the same time organic/inorganic composite materials, dry-etching polymer residues, removing resist-originated residues, antireflection coating residues, organic filling material residues, etc.

Such objects to be removed can be treated with the removing solution of the present invention, which comprises water, acid, and nonmetallic fluoride salt in specific concentrations. However, the removing solution of the invention may also contain other components (for example, rust preventives and surfactants (such as anionic surfactants, nonionic surfactants, etc.)).

Low-k films referred to as porous low-k or ultra low-k, which have dielectric constants of about 2.4 or less, may be used to lower the dielectric constants of devices. These films can be readily etched with chemical solutions. In such cases, therefore, it is preferable to use only a small amount of fluorine compounds such as hydrogen fluoride or not to use any at all. If it is desired that the damage layer formed in the interlayer dielectric after dry etching and/or ashing be left instead of being removed, it is preferable to decrease the amount of fluorine compounds or not to use any at all.

The removing solution of the present invention comprises acid, nonmetallic fluoride salt, and water. Examples of acids include HF and organic acids (carboxylic acids, sulfonic acids), among which HF and water-soluble monocarboxylic acids are preferable. This is because, in the case of water-soluble acids, removing solution of the invention remaining on a treated object such as a wafer can be easily removed by rinsing with pure water after the treatment with the removing solution of the invention.

The water in the removing solution of the invention is preferably pure water.

In this specification, the low-k film, which encompasses, for example, fluorine-containing silicon oxide films (FSG films), is an insulating film having a dielectric constant greater than 1 but not greater than about 4, preferably not greater than about 3, more preferably not greater than about 2.8, even more preferably not greater than about 2.6, and in particular not greater than about 2.5. Examples of low-k films are “Black Diamond” (trade name, product of Applied Materials, Inc.), “CORAL” (trade name, product of Novellus Systems, Inc.), “LKD” series (trade name, product of JSR Corporation), “Aurora” (trade name, product of ASM), “HSG” series (trade name, product of Hitachi Chemical Co., Ltd.), “Nanoglass” (trade name, product of Honeywell), “IPS” (trade name, product of Catalysts & Chemicals Industries Co., Ltd.), “Z₃M” (trade name, product of Dow Corning Corporation), “XLK” (trade name, product of Dow Corning Corporation), “FOx” (trade name, product of Dow Corning Corporation), “Orion” (trade name, product of Tricon), “NCS” (trade name, product of Catalysts & Chemicals Industries Co., Ltd.), and “SiLK” (trade name, product of Dow Corning Corporation).

In terms of components, low-k films may be, for example, silicon(Si)-containing compounds such as low dielectric constant films (low-k films, which may be expressed in terms of components as SiOC, SiOC:H, etc.) containing silicon bonded to OH (Si—OH bonds) and/or silicon bonded to H (Si—H bonds), etc. The main components of such low-k films may be polyallyl ethers, etc.

A low-k film is typically formed by coating or by organic plasma CVD. Low-k films formed by coating are named after their materials, and low-k films formed by organic plasma CVD are named after their materials and devices.

Examples of resists include KrF (Krypton F), ArF, F₂ resists, etc.; however, the resists in the present invention are not limited to these examples.

Examples of antireflection coatings and filling materials include those comprising organic substances as principal components, those containing inorganic substances such as silicon, etc. Antireflection coatings and filling materials containing inorganic substances such as silicon are those containing silicon, Si—OH bonds and/or Si—H bonds, etc., including those damaged by plasma ashing. Antireflection coatings and filling materials containing Si—H bonds are films containing few or no Si—CH₃ bonds and many Si—H bonds, and they are films represented by SiOₓC_{y}H_{z} having a significant Si—H absorption spectrum (2200-2300 cm⁻¹) as FT-IR measurement data, including those generally referred to as HSQ (Hydrogen Silsesquioxane).

The plasma TEOS film (P-TEOS) etching rate of the removing solution of the present invention is preferably 15 to 40 Å/min, and more preferably 20 to 35 Å/min.

Method for Removing Ashing Residue

The method of the present invention is conducted by forming via holes, trenches, etc. by dry etching; thereafter removing resist and filling material by ashing; and bringing the removing solution of the present invention into contact with an object to be removal-treated such as a semiconductor substrate having Cu/low-k multilevel interconnection structure ashing residues (which adhere to, for example, the bottom and the sidewalls of via holes and trenches, and to the upper surfaces of resist-coated low-k films, etc.) in the formation of damascene, dual damascene or the like structures for Cu/low-k multilevel interconnection structures, and in capacitor structures. The method allows the inhibition of CD losses such as slit formation in the sidewalls of the low-k film and the removal of ashing residue without corroding the copper.

After the formation of low-k film on a substrate, insulating film barriers such as SiN, SiC, and TaN films may be formed on the low-k film and etched together with the low-k film, if necessary.

The low-k film and resist usually have a thickness of about 0.01 to about 2 μm, and about 0.01 to about 10 μm, respectively. The optionally formed SiN film, SiC film, TaN film, and antireflection coating or the like usually have a thickness of about 0.01 to about 2 μm, about 0.001 to about 0.2 μm, about 0.01 to about 10 μm, and about 0.01 to about 0.1 μm, respectively.

In an object to be removal-treated such as a semiconductor substrate, the low-k film will be damaged if, after dry etching, ashing is performed with a plasma containing a large number of oxygen radicals to remove unwanted substances such as resist, antireflection coating, filling material, etching residue, etc., before the object is brought into contact with the removing solution of the present invention.

In the present invention, examples of ashing include hydrogen plasma ashing, ashing with inert gases such as He, ashing with a plasma of a mixture of gases such as He/hydrogen, and ashing using an oxygen-containing plasma with a decreased number of oxygen radicals so as not to damage the low-k film. This is because if ashing is performed using a plasma containing a large number of oxygen radicals, the low-k film will be damaged. Ashing residues are formed by performing ashing under such moderate conditions. A method referred to as “half ashing” may be used, in which ashing is stopped partway through, and unwanted substances such as resist, antireflection coating, filling material, etching residue, etc. are not completely removed. A semiconductor substrate that has been subjected to half ashing is encompassed within the objects to be treated for removal of ashing residues in the present invention.

The ashing residue removing method using the removing solution of the present invention is advantageously used to treat the objects to be removed that are produced by ashing after etching on Cu/low-k multilevel interconnection structure semiconductor substrates, etc.

The treatment of objects to be removed with the removing solution of the present invention is carried out under temperature and time conditions such that the low-k film is substantially undamaged. “Silicon-containing film or low-k film is substantially undamaged” means, for example, that the change in physical properties of the silicon-containing film or low-k film before and after the treatment using the removing solution is such that the performance of the film when used in a semiconductor substrate is not affected; that the silicon-containing film or low-k film is substantially unetched at the interface between the resist and the film, so that the cross-sectional profile of a treated object with film layers is substantially unchanged; and/or that the dielectric constant of the silicon-containing film or low-k film is substantially unchanged before and after the treatment using the removing solution. “Silicon-containing film or low-k film is substantially unetched” means that the silicon-containing film or low-k film is etched to a depth of preferably no more than about 20 nm, more preferably no more than about 10 nm, and even more preferably no more than about 5 nm. “Dielectric constant of the silicon-containing film or low-k film is substantially unchanged before and after the treatment using the removing solution” means that the change in the dielectric constant is preferably no more than about 20%, more preferably no more than about 10%, and even more preferably no more than about 5%.

Treatment with the removing solution can be conducted by, for example, immersing an object having ashing residue on a Cu/low-k multilevel interconnection structure to be removal-treated (such as a semiconductor substrate) in the removing solution of the present invention. The immersion conditions are not limited as long as they enable the removal of ashing residue and the inhibition of copper corrosion and substantially do not damage the low-k film. The immersion conditions can be suitably set according to the kind and temperature of the removing solution. The temperature of the removing solution may be, for example, about 10° C. to about 60° C., and preferably about 15° C. to about 40° C. Although the immersion time may be suitably set without limitation, it may be, for example, about 0.5 to about 10 minutes, and preferably about 1 to about 5 minutes. Moreover, a wafer may be immersed in the removing solution with stirring, if necessary. The stirring speed may be suitably set without limitation.

Furthermore, since ashing residues can be removed if the removing solution is brought into contact with an object to be treated, the solution may be supplied, for example, from above an object that is rotated while being cleaned; or the solution may be sprayed over an object for cleaning.

When ashing residues cannot be easily removed, the treatment with the removing solution of the invention may be conducted by, for example, immersing the object to be treated in the removing solution and performing ultrasonic cleaning.

After copper oxides and/or the copper oxide-containing modified copper layer formed by etching and/or ashing have been removed from a semiconductor substrate by the use of the removing solution of the invention, the semiconductor substrate can be processed into various semiconductor devices according to conventional methods (such as those mentioned in Shousetsu Handoutai CMP Gijutsu (edited by Toshiroh Doi, 2001)), furnished with copper wiring, etc.

### BEST MODE FOR CARRYING OUT THE INVENTION

The present invention is described in more detail with reference to the examples below. However, the present invention is not limited to these examples.

### EXAMPLES 1-15 AND COMPARATIVE EXAMPLES 1-5

Table 1 shows the removal of ashing residues, the CD loss of low-k films (film side etching and slit formation), copper corrosion, and P-TEOS etching rates (Å/min) in treatment using removing solutions of the present invention.

Each test was carried out using film-deposited wafers cut to specific sizes from film-deposited 8-inch wafers.

The film-deposited wafers used were as follows: Copper sputtering film-deposited wafer (film thickness: 1000 Å; 30 mm×30 mm)

P-TEOS Film Wafer (Film Thickness: 5000 Å; 15 mm×10 mm)

The wafers for measuring copper corrosion were subjected to partial removal of copper oxide film and copper using 0.1 N aqueous H₂SO₄ solution before use.

Wafers with test patterns were used to examine the removal of ashing residue and the change of the form of pattern (Critical Dimension loss) in cases where resist, antireflection coating, filling material, residues caused by dry etching and ashing (ashing residue), and copper exist together.

Wafers with test patterns were produced in the following manner. A Si substrate with a low-k film (CORAL) formed by organic plasma CVD, a P-TEOS film and a SiN film as insulating film barriers, a silicon-containing antireflection coating (BARC), and a resist film formed thereover was subjected to via etching and oxygen plasma ashing treatment with a decreased number of oxygen radicals. Filling material was then embedded in the substrate, followed by lithography, trench etching, and oxygen plasma ashing with a decreased number of oxygen radicals. An object to be treated having a dual damascene structure before the formation of copper wiring was thus obtained, which had some resist (including resist surface modified by dry etching), some antireflection coating (BARC), and ashing residue on the surface of the SiN film, and also had some filling material-originated ashing residue in via holes and trenches.

Each test was carried out by immersing a film-deposited wafer or a patterned wafer in a cleaning solution of the present invention at 23° C. for 1.5 minutes. A 1-liter container filled with pure water was then allowed to overflow with pure water at 2 liter/min while the wafer was rinsed in the container for 1 to 5 minutes and dried by N₂ purging. The P-TEOS film etching amount (Å/min) and copper corrosion amount were obtained by measuring the film thicknesses of the film-deposited wafer before and after immersion in the cleaning solution and calculating from the difference (Å) between these film thicknesses.

Electron microscopy (SEM) was used to examine cross-sectional profiles and the removability of the test-pattern resist, antireflection coating, filling material, and the residue caused by dry etching and ashing (ashing residue). The results are shown in Table 1.

Copper corrosion is evaluated as “A” when it was not more than 3 Å/min, and evaluated as “B” when it was greater than 3 Å/min.

The removal of ashing residue (polymer removal) and the change of cross-sectional profile (CD loss) are evaluated as “A” when, respectively, no ashing residue and no CD loss (slit formation and etching of hole sidewalls) were observed by SEM; and they are evaluated as “B” when, respectively, ashing residue and CD loss (formation of slits, etching of hole sidewalls) were observed by SEM.

TABLE 1

| | Acid | | Fluoride Salt | | | | | | PE- |
|---|---|---|---|---|---|---|---|---|---|
| | Chemical | Concentration | Chemical | Concentration | Ratio of | Polymer | CD | Copper | TEOS |
| Ex. | Solution | (mol/kg) | Solution | (mol/kg) | Concentrations | Removal | Loss | Corrosion | (Å/min) |
| 1 | HF | 0.1 | NH4F | 0 | | A | B | B | 26 |
| 2 | HF | 0.04 | NH4F | 0.04 | 1:1 | A | B | B | 23 |
| 3 | HF | 0.02 | NH4F | 0.2 | 1:10 | A | B | A | 29 |
| 4 | HF | 0.0175 | NH4F | 0.2625 | 1:15 | A | B | A | 24 |
| 5 | HF | 0.0175 | NH4F | 0.35 | 1:20 | A | A | A | 26 |
| 6 | HF | 0.015 | NH4F | 0.375 | 1:25 | A | A | A | 24 |
| 7 | HF | 0.015 | NH4F | 0.45 | 1:30 | A | A | A | 20 |
| 8 | HF | 0.015 | NH4F | 0.75 | 1:50 | A | A | A | 23 |
| 9 | HF | 0.015 | NH4F | 1.5 | 1:100 | A | A | A | 34 |
| 10 | HF | 0.0125 | NH4F | 2.5 | 1:200 | A | A | A | 25 |
| 11 | HF | 0.01 | NH4F | 3 | 1:300 | A | A | A | 29 |
| 12 | HF | 0.037 | NH4F | 10.81 | 1:292 | A | A | A | 27 |
| 13 | H(CF₂CF₂)₃COOH | 0.005 | NH4F | 1 | 1:200 | B | A | A | 14 |
| 14 | H(CF₂CF₂)₃COOH | 0.0075 | NH4F | 1 | 1:133 | A | A | A | 19 |
| 15 | H(CF₂CF₂)₃COOH | 0.01 | NH4F | 1 | 1:100 | A | A | A | 23 |
| 16 | H(CF₂CF₂)₃COOH | 0.0125 | NH4F | 1 | 1:80 | A | A | A | 32 |
| 16 | H(CF₂CF₂)₃COOH | 0.015 | NH4F | 1 | 1:67 | A | A | A | 36 |
| 14 | H(CF₂CF₂)₃COOH | 0.02 | NH4F | 1 | 1:50 | A | B | A | 50 |
| 15 | H(CF₂CF₂)₃COOH | 0.03 | NH4F | 1 | 1:33 | A | B | A | 65 |
| 16 | CH3COOH | 0.0125 | NH4F | 1 | 1:80 | A | A | A | 20 |
| 17 | HF | 0.0125 | NH4F | 1 | 1:80 | A | A | A | 22 |
| 18 | HF | 0.0125 | CH₃CH₂NH₃F | 1 | 1:80 | A | A | A | 25 |

CD: Critical Dimension

1. A removing solution for removing residue formed by dry etching and/or ashing on a Cu/low-k multilevel interconnection structure, wherein the removing solution comprises 0.007 to 0.04 mol/kg of acid, an organic or inorganic nonmetallic fluoride salt whose concentration is at least 20 times as great as the concentration of the acid, and water.

2. A removing solution according to claim 1, wherein the acid is HF or a carboxylic acid optionally substituted with fluorine.

3. A removing solution according to claim 1, wherein the acid is HF, acetic acid, or H(CF₂CF₂)ₙCOOH (wherein n is an integer from 2 to 4).

4. A removing solution according to claim 1, wherein the organic or inorganic nonmetallic fluoride salt is ammonium fluoride.

5. A removing solution according to claim 1, further comprising a surfactant.

6. A removing solution according to claim 1, further comprising an anticorrosive.

7. A method for removing ashing residue, comprising bringing a removing solution according to claim 1 into contact with an object to be removal-treated, wherein the object to be removal-treated has, on a surface thereof, ashing residue formed by dry etching and/or ashing on the Cu/low-k multilevel interconnection structure.

8. A removal-treated object obtained by a method according to claim 7.
